(19) United States
(12) Patent Application Publication
(10) Pub. No.: US 2014/0045288 A1
(43) Pub. Date: Feb. 13, 2014

(54) METHOD OF MANUFACTURING SEMICONDUCTOR LIGHT EMITTING DEVICE

(71) Applicant: Samsung Electronics Co., Ltd., Suwon-si (KR)

(72) Inventors: Ki Seok KIM, Hwaseong-si (KR); Je Won KIM, Seoul (KR); Ju Bin SEO, Seoul (KR); Seong Seok YANG, Hwaseong-si (KR); Sang Seok LEE, Seoul (KR); Joon Sub LEE, Seoul (KR); Jin Bock LEE, Hwaseong-si (KR)

(73) Assignee: SAMSUNG ELECTRONICS CO., LTD., Suwon-si (KR)

(21) Appl. No.: 13/965,846

(22) Filed: Aug. 13, 2013

(30) Foreign Application Priority Data
Aug. 13, 2012 (KR) 10-2012-0088588

(51) Int. Cl. H01L 33/58

(52) U.S. Cl. CPC H01L 33/58
USPC 438/31

(57) ABSTRACT

A method of manufacturing a semiconductor light emitting device includes preparing a light emitting structure including first and second conductivity type semiconductor layers and an active layer interposed therebetween, forming a plurality of seeds on at least one surface of the light emitting structure, and forming a plurality of dome-shaped protrusions by forming optical waveguide groups from the plurality of respective seeds and combining the optical waveguide groups.

### CROSS-REFERENCE TO RELATED APPLICATIONS

This application claims priority from Korean Patent Application No. 10-2012-0088588, filed on Aug. 13, 2012, in the Korean Intellectual Property Office, the disclosure of which is incorporated herein by reference in its entirety.

### BACKGROUND

1. Technical Field

Aspects of embodiments of the present disclosure relate to a method of manufacturing a semiconductor light emitting device.

2. Background

In general, a light emitting diode (LED), a type of semiconductor light emitting device, is a semiconductor device capable of generating light of various colors due to the recombination of electrons and holes at the junction between a p-type semiconductor and an n-type semiconductor, when current is applied thereto. Demand for semiconductor light emitting devices has been continuously increasing, since semiconductor light emitting devices have various advantages, such as a relatively long lifespan, low power consumption, superior initial driving characteristics, high vibration resistance, and the like, as compared to filament-based light emitting devices.

In particular, a group III-nitride semiconductor capable of emitting blue light in a short wavelength region has recently come to prominence. A nitride semiconductor light emitting device may include a light emitting structure having an n-type nitride semiconductor layer, an active layer, and a p-type nitride semiconductor layer sequentially grown therein. Nitride semiconductor devices may emit light due to the recombination of electrons and holes in the active layer, the electrons being provided from the n-type nitride semiconductor layer, and the holes being provided from the p-type nitride semiconductor layer.

However, a possible disadvantage of semiconductor light emitting devices includes that a considerable amount of light may be totally internally reflected within the interior of the light emitting device, rather than being emitted outwardly. This may be due to a difference in refractive indices between an external material and an internal material of the light emitting device from which light is generated, thereby lowering light extraction efficiency.

Although technology of forming a photonic crystal such as a nanorod on a light extraction surface has been suggested in order to improve light extraction efficiency, the structure of a nanorod may generate a void at the time of forming a current spreading layer on the light extraction surface in order to obtain light generation efficiency. Further, a seed layer provided in the forming of a nanorod may remain on the entirety of the light extraction surface and may deteriorate light transmittance, thereby causing an increase in a required driving voltage.

### SUMMARY

The present disclosure provides a method of efficiently manufacturing a semiconductor light emitting device having improved light extraction efficiency.

According to an aspect of an embodiment, there is provided a method of manufacturing a semiconductor light emitting device, the method including: preparing a light emitting structure including first and second conductivity type semiconductor layers and an active layer interposed therebetween; forming a plurality of seeds on at least one surface of the light emitting structure; and forming a plurality of dome-shaped protrusions by forming optical waveguide groups from the plurality of respective seeds and combining the optical waveguide groups.

The at least one surface of the light emitting structure may be a light emitting surface of the second conductivity type semiconductor layer.

The forming of the plurality of seeds may include: forming mask patterns on the at least one surface of the light emitting structure so as to partially expose the at least one surface; and forming the plurality of seeds on the at least one surface of the light emitting structure partially exposed by the mask patterns.

The mask patterns may have a preset interval, the preset interval being greater than a diameter of the dome-shaped protrusions.

The forming of the mask patterns may include: forming a photo resist on the at least one surface of the light emitting structure; and forming patterns on the photo resist using laser interference lithography (LIL) or photolithography.

The forming of the plurality of seeds on the at least one surface of the light emitting structure partially exposed by the mask patterns may include: depositing donor seeds on the mask patterns; and oxidizing the donor seeds.

The depositing of the donor seeds may be performed through an electron beam evaporation method or a sputtering method.

The method of manufacturing a semiconductor light emitting device may further include: removing the mask patterns before oxidizing the donor seeds after the depositing of the donor seeds.

The donor seeds may include zinc (Zn) metal.

The oxidizing of the donor seeds may be performed in a reaction solution including precursors respectively providing zinc ions and oxygen ions.

The precursors providing the zinc ions may include at least one of zinc nitrate, zinc sulfate, and zinc acetate.

The reaction solution may be a solution including an ammonia solution and having a pH of about 10 or above.

The plurality of dome-shaped protrusions may include a zinc oxide (ZnO) material.

The plurality of dome-shaped protrusions may be formed of a material having a refractive index lower than that of the second conductivity type semiconductor layer.

The plurality of dome-shaped protrusions may have a refractive index of about 1.2 to 1.8.

The forming of the plurality of dome-shaped protrusions may be performed in first and second immersion liquids through hydrothermal synthesis.

The first immersion liquid may be a neutral solution having a pH of about 7.

The second immersion liquid may be a solution having a pH of about 10 or above.

The second immersion liquid may include a horizontal growth inducing agent.

The light emitting struture may include a p-type semiconductor layer, an active layer, and an n-type semiconductor layer sequentially stacked on a conductive substrate; and the second conductivity type semiconductor layer may be an n-type semiconductor layer.

The light emitting struture may include an n-type semiconductor layer, an active layer, and a p-type semiconductor layer sequentially stacked on an insulating substrate; and the second conductivity type semiconductor layer may be a p-type semiconductor layer.

The method of manufacturing a semiconductor light emitting device may further include: forming a current spreading layer on the light emitting surface on which the dome-shaped protrusions are formed.

The current spreading layer may include indium tin oxide (ITO).

### BRIEF DESCRIPTION OF THE DRAWINGS

The above and other aspects, features and other advantages will be more clearly understood from the following detailed description taken in conjunction with the accompanying drawings, in which:

FIG. 1 is a perspective view of an example of a semiconductor light emitting device according to an embodiment of the present disclosure;

FIG. 2 is a perspective view of an example of a semiconductor light emitting device according to another embodiment of the present disclosure;

FIG. 3 is a flow chart describing an example of a method of manufacturing a semiconductor light emitting device according to an embodiment of the present disclosure;

FIG. 4 is an electron micrograph showing a process of forming dome-shaped protrusions according to the embodiment of the present disclosure described in FIG. 3.

FIGS. 5 through 9 are process perspective views illustrating a process of manufacturing a semiconductor light emitting device according to the embodiment of the present disclosure described in FIG. 3;

FIG. 10 is a view illustrating a process of forming the dome-shaped protrusions from optical waveguide groups according to the embodiment of the present disclosure described in FIG. 3;

FIG. 11 is an electron micrograph showing a light emitting surface on which the dome-shaped protrusions are formed, according to the embodiment of the present disclosure described in FIG. 3; and

FIGS. 12A and 12B are graphs illustrating light emitting effects of the semiconductor light emitting device, according to the embodiment of the present disclosure described in FIG. 3.

### DETAILED DESCRIPTION

Hereinafter, embodiments will be described in detail with reference to the accompanying drawings. The embodiments may, however, be embodied in many different forms and should not be construed as being limited to the embodiments set forth herein. Rather, these embodiments are provided so that this disclosure will be thorough and complete. In the drawings, the shapes and dimensions of elements may be exaggerated for clarity, and the same reference numerals will be used throughout to designate the same or like elements.

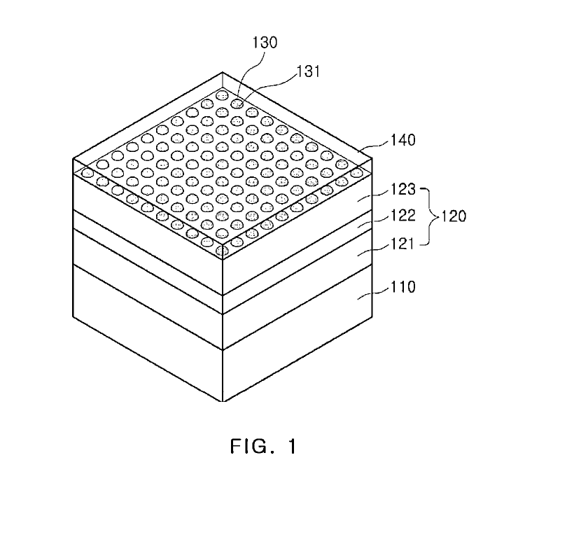

FIG. 1 is a perspective view of a semiconductor light emitting device according to an embodiment of the present disclosure.

Referring to FIG. 1, a semiconductor light emitting device may include a substrate 110, a light emitting structure 120 formed on the substrate 110, a plurality of dome-shaped protrusions 130 formed on at least one surface of the light emitting structure 120, and a current spreading layer 140 formed to cover the plurality of dome-shaped protrusions 130 on the surface on which the plurality of dome-shaped protrusions 130 are formed. In addition, the at least one surface of the light emitting structure 120, on which the plurality of dome-shaped protrusions 130 are formed, may be a light emitting surface of a second conductivity type semiconductor layer 123 of the light emitting structure 120.

The light emitting structure 120 may include a first conductivity type semiconductor layer 121, an active layer 122, and a second conductivity type semiconductor layer 123 stacked therein. Each of the first conductivity type semiconductor layer 121 and the second conductivity type semiconductor layer 123 may be a semiconductor layer doped with a p-type or n-type impurity. In addition, the first and second conductivity type semiconductor layers 121 and 123 may be formed of a nitride semiconductor, for example, a material having a compositional formula of AlₓIn_{y}Ga_{(1-x-y)}N, where 0≦x≦1, 0≦y≦1, and 0≦x+y≦1 in some embodiments. The active layer 122 interposed between the first and second conductivity type semiconductor layers 121 and 123 may emit light having a predetermined level of energy through electron-hole recombination. The active layer 122 may have a multi-quantum well (MQW) structure in which quantum well and quantum barrier layers are alternately stacked. The multi-quantum well structure may employ an InGaN/GaN structure, for example.

The current spreading layer 140 may be formed of a material that exhibits electrical ohmic-characteristics with regard to the second conductivity type semiconductor layer 123. The current spreading layer 140 may be formed of a transparent conductive oxide that has a high level of light transmittance and relatively excellent ohmic-contact performance among materials used for a transparent electrode, for example, indium tin oxide (ITO).

Here, the light emitting structure 120 may be provided on a conductive substrate 110. That is, the substrate 110 may be a conductive substrate serving to apply an electrical signal to a p-type semiconductor layer. The conductive substrate 110 may be formed of a material including any one of Au, Ni, Al, Cu, W, Si, Se, GaAs, or for example, a material formed by doping a silicon (Si) substrate with aluminum (Al). The light emitting structure 120 may include a p-type semiconductor layer 121, an active layer 122, and an n-type semiconductor layer 123 sequentially stacked on the conductive substrate 110. In this example, a light emitting surface may be an upper surface of the n-type semiconductor layer 123.

In other examples, the light emitting structure may be provided on an insulating substrate.

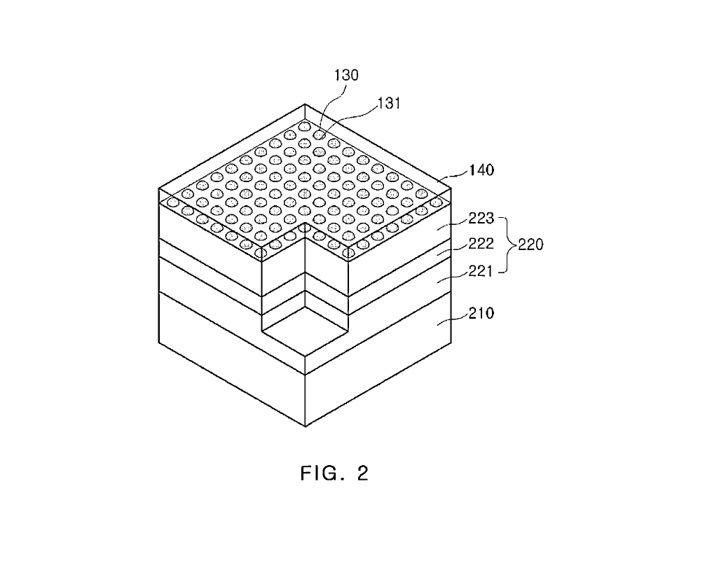

FIG. 2 illustrates a light emitting structure 220 provided on an insulating substrate 210.

Referring to FIG. 2, the light emitting structure 220 may include first and second conductivity type semiconductor layers 221 and 223 on the insulating substrate 210 and an active layer 222 interposed therebetween. In this case, the first and second conductivity type semiconductor layers 221 and 223 may be an n-type semiconductor layer and a p-type semiconductor layer, respectively. Further, the insulating substrate 210 may be formed of a material such as sapphire, SiC, MgAl2O₄, MgO, undoped GaN, or the like. In this example, a light emitting surface may be an upper surface of the p-type semiconductor layer 221, and the light emitting structure 220 may be formed such that the p-type semiconductor layer 221, the active layer 222, and the n-type semiconductor layer 223 are partially mesa etched to partially expose an upper surface of the n-type semiconductor layer 223, in order to allow an electrical signal to be applied to the n-type semiconductor layer 223.

Meanwhile, the light emitting structures 120 and 220 may have a considerable portion of light generated in the active layer not emitted outwardly due to a difference between an internal refractive index and an external refractive index thereof, thereby lowering light efficiency. For example, a material forming the active layers 122 and 222 in which light is generated may have a refractive index of about 1.9 to 2.0 and the second conductivity type semiconductor layers 123 and 223 from which light is extracted may have a refractive index of about 1.7 to 1.8, while an external material, for example, air, present outside the light emitting structures 120 and 220 may have a refractive index of about 1.0. Thus, a considerable amount of light generated in the active layers 122 and 222 may not be extracted outwardly due to a difference in refractive indices between internal and external materials of the light emitting structures 120 and 220, and may be totally reflected from light emitting surfaces of the second conductivity type semiconductor layers 123 and 223.

Accordingly, in some embodiments, the plurality of dome-shaped protrusions 130 may be formed on the light emitting surface in order to gradually reduce a difference between an internal refractive index and an external refractive index of the light emitting structure 120 or 220 and improve light extraction efficiency. First, structural characteristics of the dome-shaped protrusions 130 will be described and a method of forming the dome-shaped protrusions 130 will be provided later.

Referring to FIGS. 1 and 2, the semiconductor light emitting device according to the embodiment may include a plurality of dome-shaped protrusions 130 formed on the light emitting surface of the second conductivity type semiconductor layer 123 or 223. The dome-shaped protrusions 130 may be formed of a material having a refractive index between that of the second conductivity type semiconductor layer 123 or 223 and that of the external material (air), and preferably, may be a material including zinc oxide (ZnO), zinc sulfide (ZnS), or cadmium sulfide (CdS).

The plurality of dome-shaped protrusions 130 may have nano-sized dome shapes and may be respectively formed from a plurality of seeds 131 patterned on the at least one surface of the light emitting structure 120 or 220. For example, the seeds 131 may be formed on the light emitting surface of the second conductivity type semiconductor layer 123 or 223. Since the dome shaped protrusions 130 may have an area gradually reduced upwardly in a light extraction direction, the refractive index thereof may be gradually lowered, for example, from about 1.8 to 1.2 upwardly in the light extraction direction to effectively reduce a difference in refractive indices between the internal material and the external material thereof. In addition, when the current spreading layer 140 is disposed on the upper surface of the second conductivity type semiconductor layer 123 or 223 on which the dome-shaped protrusions 130 are formed, a defect of voids occurring between the second conductivity type semiconductor layer 123 or 223 and the current spreading layer 140 may be effectively reduced as compared to the case of protrusions having other shapes, for example, irregular nano-sized rod shapes.

Hereinafter, a method of manufacturing the semiconductor light emitting device described above will be explained.

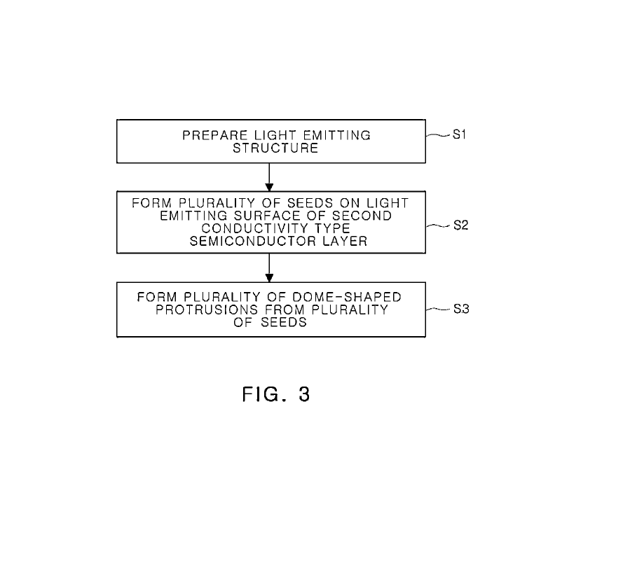

FIG. 3 is a flow chart describing an example of a method of manufacturing a semiconductor light emitting device according to an embodiment of the present disclosure.

In the example shown in FIG. 3, the light emitting structure including the first and second conductivity type semiconductor layers and the active layer interposed therebetween is first prepared (S1).

As illustrated in FIGS. 1 and 2, the light emitting structure may be provided on the conductive substrate 110 or the insulating substrate 220, and the first conductivity type semiconductor layers 121, 221, the second conductivity type semiconductor layers 123, 223, and the active layers 122, 222 may be formed using a semiconductor layer growth process such as metal organic chemical vapor deposition (MOCVD), molecular beam epitaxy (MBE), hydride vapor phase epitaxy (HVPE), or the like.

After preparing the light emitting structure in S1, the plurality of seeds 131 are formed on the at least one surface of the light emitting structure (S2).

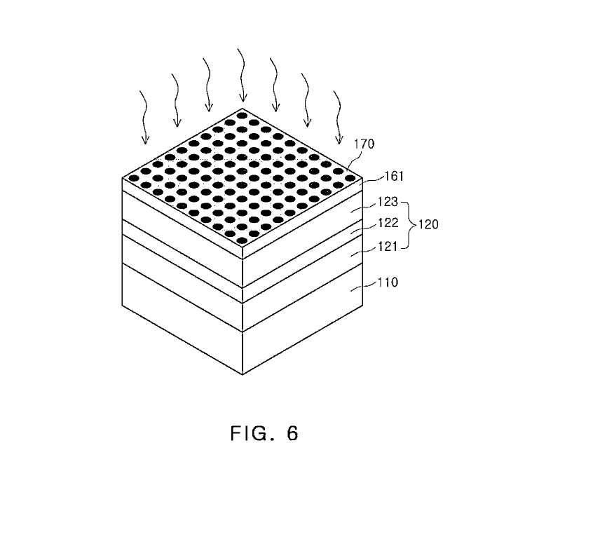

The at least one surface of the light emitting structure 120, 220 may be a light emitting surface of the second conductivity type semiconductor layer 123, 223, but is not limited thereto. The seeds 131 may be obtained by oxidizing donor seeds 170 (see FIG. 6) and may be patterned in positions in which the plurality of dome-shaped protrusions 130 will be formed on the light emitting surface. That is, the seeds 131 are formed to be patterned on the light emitting surface of the second conductivity type semiconductor layer 123, 223, whereby the positions in which the plurality of dome-shaped protrusions 130 will be formed may be defined. Accordingly, a plurality of uniformly patterned dome-shaped protrusions 130 may be obtained and the seeds 131 may not remain in positions in which the protrusions 130 are not formed on the light emitting surface, such that defects of degrading light transmittance of the semiconductor light emitting device and increasing driving voltage may be effectively improved.

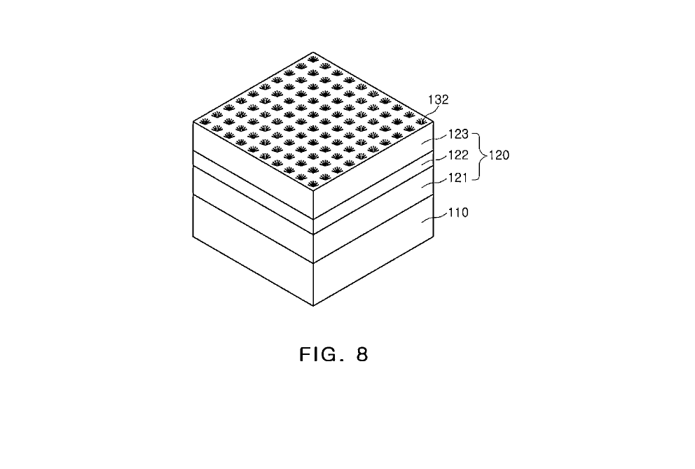

After forming the seeds 131 on the light emitting surface, optical waveguide groups 132 (see FIG. 8) may be formed from the plurality of respective seeds, and the optical waveguide groups combined to form the plurality dome-shaped protrusions 130 (S3).

The operation (S3) may be performed using hydrothermal synthesis. That is, after the light emitting structure 120, 220 having the plurality of seeds 131 patterned thereon is first immersed in a first immersion liquid having a neutral pH of about 7, the plurality of seeds 131 are respectively vertically grown (e.g. grown in a c-axis direction), to form the plurality of optical waveguide groups 132.

Thereafter, the plurality of optical waveguide groups 132 formed in the process may be horizontally grown to form the plurality of dome-shaped protrusions 130. The horizontal growth may be performed in a second immersion liquid and in this example, the second immersion liquid may be an alkaline solution having a pH of about 10 or above.

The detailed descriptions regarding the forming of the first immersion liquid and the optical waveguide groups 132, and the forming of the second immersion liquid and the dome-shaped protrusions 130 will be described later.

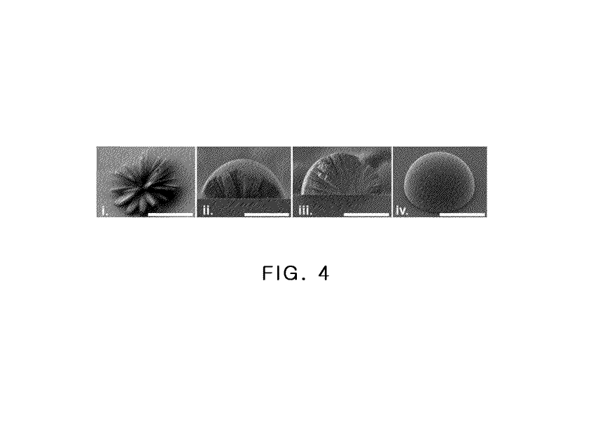

FIG. 4 is an electron micrograph showing a process in which optical waveguide groups are combined to form a dome-shaped protrusion 130 according to the operation (S3). The vertical growth and the horizontal growth of the seeds were performed at a temperature of 60° C. and formed by immersing the seeds 131 in the second immersion liquid for about 3 hours.

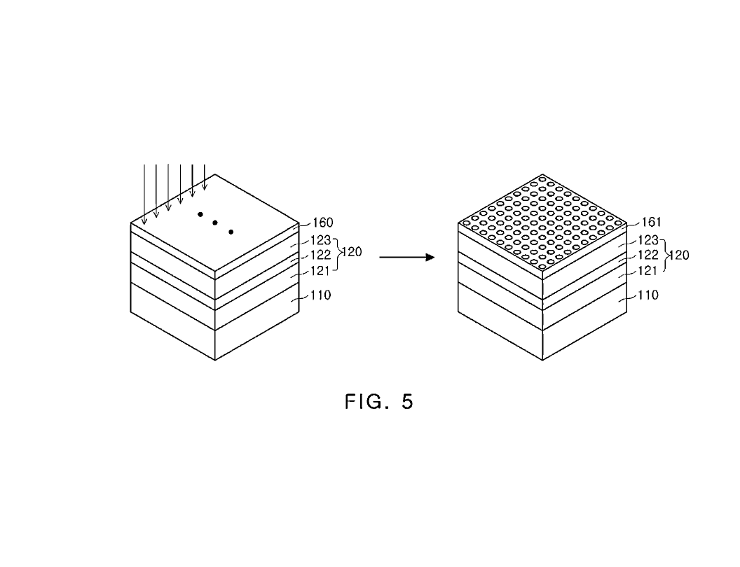

Hereinafter, a method of manufacturing the semiconductor light emitting device according to the embodiment of the present disclosure described in FIG. 3 will be described in detail with reference to FIG. 5 through FIG. 9.

FIG. 5 through FIG. 7 are views illustrating the forming of the plurality of seeds 131 on the at least one surface of the light emitting structure 120 (S2) after the preparing of the light emitting structure 120 (S1).

This example illustrates the case in which the light emitting structure 120 is provided on a conductive substrate 110 for the convenience of explanation and understanding, but the inventive concept is not limited thereto and may also be applied to a light emitting structure 220 provided on an insulating substrate 210.

Referring to FIG. 5, the forming of the plurality of seeds on the at least one surface of the light emitting structure 120 (S2) may include forming a patterned mask 161 on the at least one surface.

In this example, the at least one surface of the light emitting structure 120 on which the seeds 131 are formed may be the light emitting surface of the second conductivity type semiconductor layer 123 in the light emitting structure 120. The light emitting structure 120 may be formed by sequentially stacking the p-type semiconductor layer 121, the active layer 122, and the n-type semiconductor layer 123 on the conductive substrate 110. In this case, the light emitting surface of the second conductivity type semiconductor layer 123 may be an upper surface of the n-type semiconductor layer 123.

The patterned mask 161 may be provided to pattern the seeds 131 on the light emitting surface and may be obtained by forming a mask 160 on the n-type semiconductor layer 123 and then removing portions thereof. For example, in an example in which photo resist is used as the mask 160, patterns may be formed by using a phenomenon in which a photosensitive portion is not dissolved (negative type) or dissolved (positive type) through laser interference lithography (LIL) or photolithography.

The patterns may be appropriately controlled in consideration of compactness or distribution of the dome-shaped protrusions 130 formed from the seeds 131 in a subsequent process.

In addition, in order to prevent the plurality of dome-shaped protrusions 130 from being coupled to each other, an interval between the patterns may be set to be greater than a diameter of the dome-shaped protrusions 130.

Referring to FIG. 6, operation (S2) may further include depositing donor seeds 170 on the patterned mask 161.

The donor seeds 170 may become seeds 131 through oxidation performed in a subsequent process. In some example, the donor seeds 170 may be a material including zinc (Zn) metal.

Meanwhile, when the donor seeds 170 are deposited through a high temperature process such as metal organic chemical vapor deposition (MOCVD), the patterned mask 161 may be damaged due to heat and thus, preformed uniform patterns may be deformed. Accordingly, it may be necessary to deposit the donor seeds 170 at low temperatures. Therefore, the donor seeds 170 may be deposited using an electron beam evaporation method or a sputtering method.

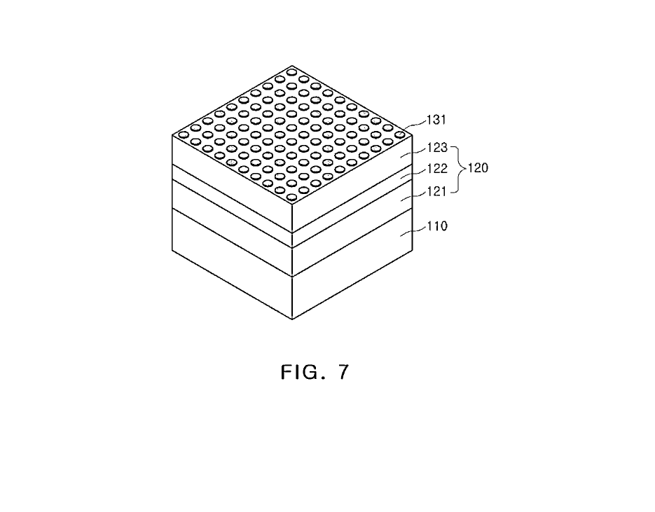

FIG. 7 is a view schematically illustrating a state in which the operation S2 has been completed. That is, referring to FIG. 7, the operation S2 may further include the removing of the patterned mask 161 and forming the seeds 131 by oxidizing the donor seeds 170.

The removing of the patterned mask 161 may be appropriately performed depending on properties of a mask 160 used therefore. For example, when photo resist is used as a mask 160, a process of removing the mask 160 may be a lift off process using acetone, a base solvent or the like as a solvent.

The seeds 131 may be formed through a process of oxidizing the donor seeds 170, and may be formed of a material including zinc oxide (ZnO).

The oxidation may be performed in a gaseous state method or in a liquid state method. The gaseous state method may be performed by chemically reacting the donor seeds, for example, zinc metal, with oxygen gas. The liquid state method may be performed by oxidizing the donor seeds, such as zinc metal, in a reaction solution having a pH of about 10 or above. For example, when zinc metal is used as the seed donor 170, hydrothermal synthesis may be used as a liquid phase oxidation method. The hydrothermal synthesis may be a method commonly used at the time of ZnO synthesis and may have advantages such as a simple process and large-area applicability.

When the seeds 131 formed of zinc oxide are formed using hydrothermal synthesis, a chemical bond between a zinc ion and an oxygen ion may be induced by applying conditions such as an appropriate temperature, pressure and the like to a reaction solution having a pH of about 10 or above and including precursors to provide zinc ions and oxygen ions, respectively, such that the zinc oxide may be formed from donor seeds 170 of zinc metal.

In this example, the precursors for zinc ions may include at least one of zinc nitrate, zinc sulfate, and zinc acetate. Precursors for oxygen ions may include at least one of an ammonia (NH₄OH) solution, hexamethylenetetramine (HMTylC₆H₁₂N₄), hydrogen peroxide (H₂O₂), lithium hydroxide (LiOH), sodium hydroxide (NaOH) or the like.

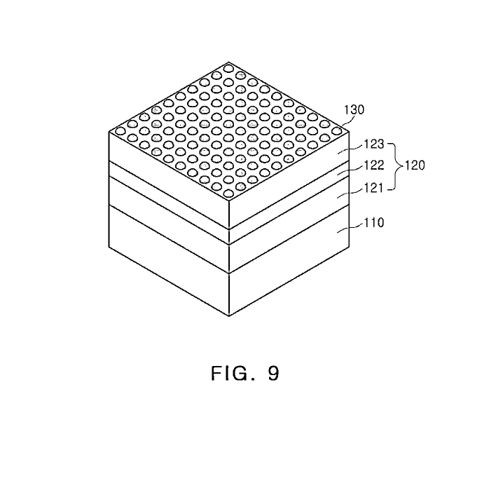

FIG. 8 and FIG. 9 are views schematically illustrating a process in which optical waveguide groups 132 are formed from the plurality of respective seeds 131, and the optical waveguide groups 132 are combined to form the plurality dome-shaped protrusions 130 as indicated in S3.

Referring to FIG. 8, the plurality of the optical waveguide groups 132 are formed on the light emitting structure 120. The optical waveguide groups 132 are obtained by growing the plurality of seeds 131 vertically, and may be formed by immersing the upper surface of the second conductivity type semiconductor layer 123 of the light emitting structure 120 on which the plurality of seeds 131 are formed, in the first immersion liquid having a pH of about 7.

When the seeds 131 are formed using zinc oxide, the first immersion liquid may be a neutral solution having a pH of about 7 and including precursors respectively providing zinc ions and oxygen ions. In this example, the precursors may include at least one of zinc nitrate, zinc sulfate, and zinc acetate that provide zinc ions and an ammonia (NH₄OH) solution, hexamethylenetetramine (HMTylC₆H₁₂N₄), or the like that provides oxygen ions.

When the upper surface of the second conductivity type semiconductor layer 123 is immersed in the first immersion liquid and an appropriate temperature, such as about 50° C. to about 100° C., or pressure is applied thereto, the plurality of seeds 131 formed on the upper surface of the second conductivity type semiconductor layer 123 may react with the first immersion liquid and be respectively vertically grown, and the plurality of optical waveguide groups 132 may be formed from the plurality of seeds 131.

Thereafter, the optical waveguide groups 132 are combined to form the domed shaped protrusions 130.

The combination may be performed by inducing the horizontal growth of the optical waveguide groups 132.

FIG. 9 illustrates the plurality of dome-shaped protrusions 130 formed by immersing the upper surface of the second conductivity type semiconductor layer 123 of the light emitting structure 120, on which the optical waveguide groups 132 are formed, in the second immersion liquid to induce the combination of the optical waveguide groups 132.

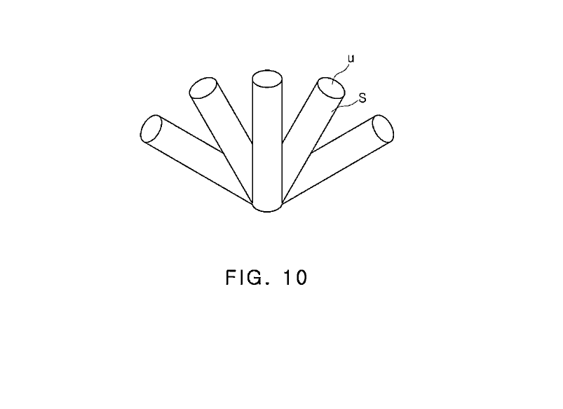

The process will be explained in detail with reference to FIG. 10.

Referring to FIG. 10, optical waveguides of each of the optical waveguide groups 132 formed through the reaction with the first immersion liquid may respectively have a cylindrical shape. Each optical waveguide has a cylindrical surface S exhibiting anionic properties and a cylindrical upper surface u exhibiting cationic properties due to a polarization phenomenon when brought into contact with a solution having a pH of about 10 or above. Here, when an anionic material such as an anionic polymer is added, the cylindrical upper surface u, which is vertically grown, may contact the anionic material and thus no longer be grown, while the cylindrical surface S not in contact with the anionic material is continually grown, the respective optical waveguides of each optical waveguide group 132 are combined with one another to form the dome-shaped protrusion 130. That is, the second immersion liquid, inducing the combination, may be an alkaline solution having a pH of about 10 or above and including precursors respectively providing zinc ions and oxygen ions. The second immersion liquid may further include a horizontal growth inducing agent such as an anionic polymer. In this example, the precursors may include at least one of zinc nitrate, zinc sulfate, and zinc acetate that provide zinc ions and an ammonia (NH₄OH) solution, hexamethylenetetramine (HMTylC₆H₁₂N₄), or the like that provides oxygen ions.

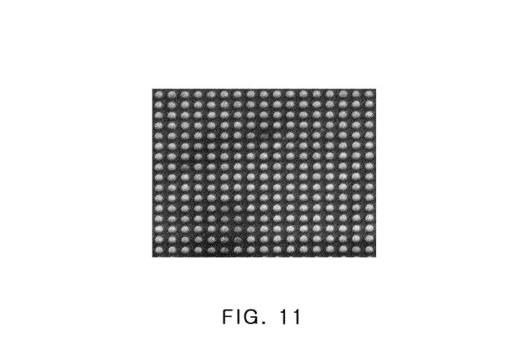

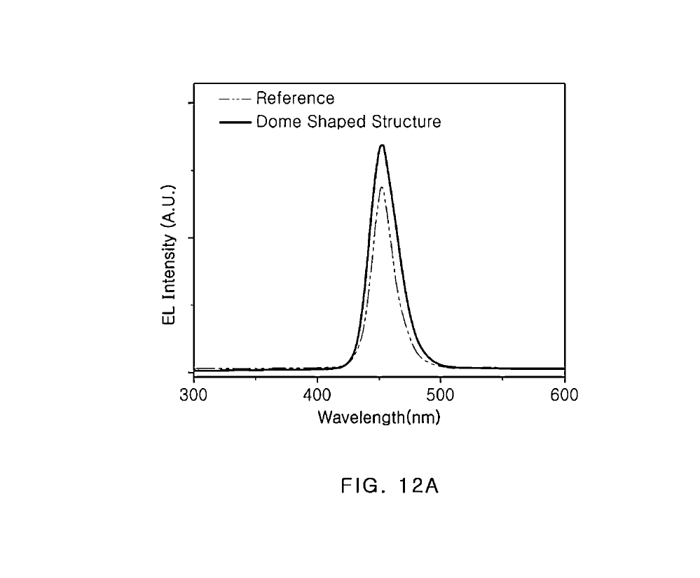

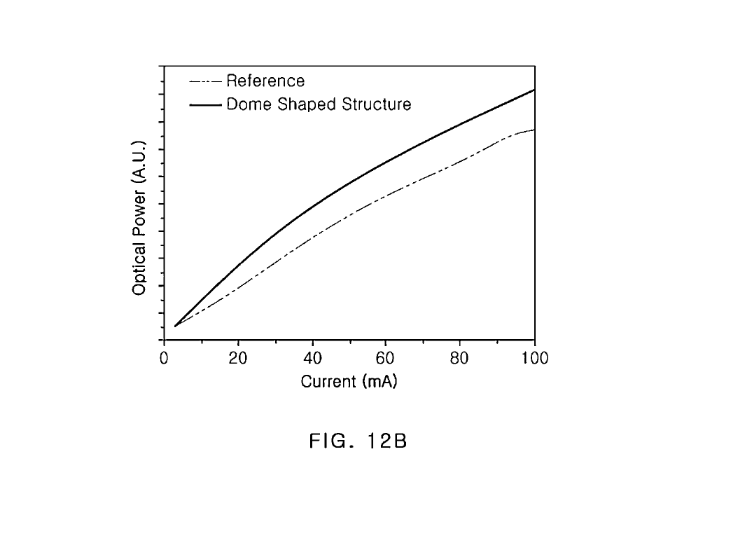

FIG. 11 is an electron micrograph showing the light emitting surface of the semiconductor light emitting device, on which the plurality of dome-shaped protrusions 130 are formed thereon, according to an embodiment of the present disclosure; and FIGS. 12A and 12B are graphs illustrating light emitting effects of the semiconductor light emitting device, according to the embodiment of the present disclosure.

Referring to FIGS. 12A and 12B, the semiconductor light emitting device has higher light emitting intensity in the same wavelength and effectively improved light output in comparison to the related art device consuming the same level of current, as compared to a semiconductor light emitting device having no dome-shaped protrusions.

As set forth above, according to some embodiments of the present disclosure, dome-shaped protrusions 130 are provided on a light emitting surface, such that a method of effectively manufacturing a semiconductor light emitting device having improved light extraction efficiency can be obtained.

While the present invention has been shown and described in connection with the embodiments, it will be apparent to those skilled in the art that modifications and variations can be made without departing from the spirit and scope of the present inventive concept as defined by the appended claims.

What is claimed is:

1. A method of manufacturing a semiconductor light emitting device, the method comprising:
preparing a light emitting structure including first and second conductivity type semiconductor layers and an active layer interposed therebetween;
forming a plurality of seeds on at least one surface of the light emitting structure; and
forming a plurality of dome-shaped protrusions by forming optical waveguide groups from the plurality of respective seeds and combining the optical waveguide groups.

2. The method of claim 1, wherein the forming of the plurality of seeds includes:
forming mask patterns on the at least one surface of the light emitting structure so as to partially expose the at least one surface; and
forming the plurality of seeds on the at least one surface of the light emitting structure, partially exposed by the mask patterns.

3. The method of claim 2, wherein the mask patterns have a preset interval, the preset interval being greater than a diameter of the dome-shaped protrusions.

4. The method of claim 2, wherein the forming of the mask patterns includes:
forming photo resist on the at least one surface of the light emitting structure; and
forming patterns on the photo resist using laser interference lithography (LIL) or photolithography.

5. The method of claim 2, wherein the forming of the plurality of seeds on the at least one surface of the light emitting structure partially exposed by the mask patterns includes:
depositing donor seeds on the mask patterns; and
oxidizing the donor seeds.

6. The method of claim 5, wherein the depositing of the donor seeds is performed through an electron beam evaporation method or a sputtering method.

7. The method of claim 5, further comprising:
removing the mask patterns before oxidizing the donor seeds after the depositing of the donor seeds.

8. The method of claim 5, wherein the donor seeds include zinc (Zn) metal.

9. The method of claim 8, wherein the oxidizing of the donor seeds is performed in a reaction solution including precursors respectively providing zinc ions and oxygen ions.

10. The method of claim 9 wherein the precursors providing the zinc ions include at least one of zinc nitrate, zinc sulfate, and zinc acetate.

11. The method of claim 9, wherein the reaction solution is a solution including an ammonia solution and having a pH of 10 or above.

12. The method of claim 1, wherein the plurality of dome-shaped protrusions include a zinc oxide (ZnO) material.

13. The method of claim 1, wherein the plurality of dome-shaped protrusions are formed of a material having a refractive index lower than that of the second conductivity type semiconductor layer.

14. The method of claim 13, wherein the plurality of dome-shaped protrusions have a refractive index of about 1.2 to 1.8.

15. The method of claim 1, wherein the forming of the plurality of dome-shaped protrusions is performed in first and second immersion liquids through hydrothermal synthesis.

16. The method of claim 15, wherein the first immersion liquid is a neutral solution having a pH of about 7.

17. The method of claim 15, wherein the second immersion liquid is a solution having a pH of about 10 or above.

18. The method of claim 15, wherein the second immersion liquid includes a horizontal growth inducing agent.

19. The method of claim 1, further comprising:
forming a current spreading layer on the light emitting surface on which the dome-shaped protrusions are formed.

20. The method of claim 19, wherein the current spreading layer includes indium tin oxide (ITO).
